(19) United States
(12) Patent Application Publication
(10) Pub. No.: US 2026/0361270 A1
(43) Pub. Date: Nov. 12, 2026

(54) Cross-Coupled Capacitive Network for Intermodulation Distortion Cancellation

(71) Applicant: Google LLC, Mountain View, CA (US)

(72) Inventor: Saeid Rezaei, Waterloo (CA)

(73) Assignee: Google LLC, Mountain View, CA (US)

(21) Appl. No.: 19/718,996

(22) Filed: Jun. 24, 2026

(51) Int. Cl. H03D 7/12

(52) U.S. Cl. CPC H03D 7/12

(57) ABSTRACT

Radio frequency communication systems utilize frequency translation operations that benefit from maintained signal linearity. A mixer circuit for processing radio frequency signals includes a mixing core having a first transistor and a second transistor. The mixing core receives a differential local oscillator signal from a local oscillator input comprising a first node and a second node. A cross-coupled capacitive network is disposed between the local oscillator input and output terminals of the mixing core. A first capacitor is coupled between the first local oscillator node and a second output terminal, and a second capacitor is coupled between the second local oscillator node and a first output terminal. This cross-coupled arrangement applies an anti-phase portion of the differential local oscillator signal to the output terminals, canceling intermodulation distortion components to manage a linearity response.

### SUMMARY

This document describes techniques and apparatuses, implemented in radio frequency communication systems directed at a cross-coupled capacitive network for intermodulation distortion cancellation. The described techniques and apparatuses provide a passive mechanism to cancel third-order intermodulation distortion. This manages the linearity response of the resulting radio frequency signals and creates a peak in the third-order input intercept point (IIP3) of a mixer circuit without utilizing active cancellation circuitry.

In general, a first aspect of the present disclosure relates to a mixer circuit. The mixer circuit includes a first local oscillator (LO) node and a second LO node configured to receive a differential LO signal. The differential LO signal includes a first LO phase and a second LO phase. The mixer circuit further includes a mixing core having a first transistor and a second transistor. The first transistor includes a first output terminal and a first control terminal coupled to the first LO node to receive the first LO phase. The second transistor includes a second output terminal and a second control terminal coupled to the second LO node to receive the second LO phase. A radio frequency (RF) stage is coupled to the first output terminal and the second output terminal. An intermediate frequency (IF) stage is coupled to the mixing core and is configured to output an IF signal. The mixer circuit also includes a cross-coupled capacitive network that includes a first capacitor coupled between the first LO node and the second output terminal, and a second capacitor coupled between the second LO node and the first output terminal.

This document also describes methods for operating the above-summarized mixer circuit and other apparatuses set forth herein, as well as systems and means for implementing these circuits.

This Summary introduces simplified concepts for a cross-coupled capacitive network for intermodulation distortion cancellation, which is further described below in the Detailed Description and is illustrated in the Drawings. This Summary is intended neither to identify core features of the claimed subject matter nor for use in determining the scope of the claimed subject matter.

### BRIEF DESCRIPTION OF THE DRAWINGS

The details of one or more aspects of a cross-coupled capacitive network for intermodulation distortion cancellation are described throughout the disclosure, with reference to the drawings. The use of the same reference numbers in different instances in the detailed description and the drawings indicates same or similar elements:

FIG. 1 illustrates a block diagram of an example transceiver front end for a cross-coupled capacitive network for intermodulation distortion cancellation;

FIG. 2 illustrates a block diagram of an example mixer circuit for a cross-coupled capacitive network for intermodulation distortion cancellation;

FIG. 3 illustrates a schematic diagram of an example mixer circuit for a cross-coupled capacitive network for intermodulation distortion cancellation;

FIG. 4A illustrates a graph depicting voltage and phase versus capacitance data for a cross-coupled capacitive network for intermodulation distortion cancellation;

FIG. 4B illustrates a graph depicting frequency sweep data for a cross-coupled capacitive network for intermodulation distortion cancellation; and

FIG. 5 illustrates a flow diagram of an example method for a cross-coupled capacitive network for intermodulation distortion cancellation.

### DETAILED DESCRIPTION

Radio frequency communication systems frequently employ frequency translation to process transmitted and received signals across various frequency bands, such as millimeter-wave frequencies. Within these environments, transceivers may utilize a mixer circuit to shift an incoming radio frequency signal to an intermediate frequency for subsequent processing. This frequency translation process generally involves mixing the radio frequency signal with a locally generated oscillator signal. In such high-frequency operating environments, managing the linearity of the resulting signals can help maintain overall signal integrity, bandwidth efficiency, and communication system performance.

To manage signal linearity, a communication system may utilize a mixer circuit equipped with a cross-coupled capacitive network. The mixer circuit generally includes a mixing core configured to receive the radio frequency signal and the local oscillator signal. The local oscillator signal may be a differential signal comprising distinct phases provided via a pair of local oscillator input nodes. The cross-coupled capacitive network can be disposed between the local oscillator input nodes and the respective output terminals of the mixing core, providing a specific, passive signal pathway across the circuit.

During operation, the cross-coupled capacitive network routes portions of the differential local oscillator signal directly to the output terminals. Specifically, the network can be arranged such that a phase of the local oscillator signal driving one side of the mixing core is capacitively coupled to the output terminal of the opposite side of the mixing core. By cross-coupling these connections, an anti-phase, or inverted, portion of the local oscillator signal is applied to the intermediate frequency output. This anti-phase application introduces a controlled signal that physically interacts with the intermediate frequency outputs of the signal translation process.

This cross-coupled signal routing provides a mechanism for managing a harmonic profile of the output and canceling intermodulation distortion. By applying the anti-phase portion of the differential local oscillator signal to the output terminals, the capacitively coupled signal can destructively interfere with unwanted distortion components, such as third-order intermodulation distortion, generated internally during the frequency mixing process. Canceling these components can yield a technical effect of creating a peak in a third-order input intercept point response curve. Consequently, the mixer circuit may provide an elevated linearity response at targeted operating frequencies without substantially altering the fundamental output voltage of the intermediate frequency signal.

Because the cross-coupled capacitive network can rely on passive components, these technical effects may be realized without utilizing active cancellation circuitry that might otherwise consume additional direct current power or utilize a larger physical footprint. In some implementations, the capacitance values within the cross-coupled network may be structurally sized to substantially match parasitic characteristics of the mixing core. In other implementations, the network may comprise a switchable bank of capacitors configured to be adjustable to tune the linearity response and align the cancellation effects with different target operating frequencies. As a result, the described techniques provide an adaptable mechanism for managing signal integrity in compact, high-frequency communication environments.

### Example Environment

The following discussion describes an operating environment, techniques that may be employed in the operating environment, and various devices or systems in which components of the operating environment may be embodied. In the context of the present disclosure, reference is made to the operating environment by way of example only.

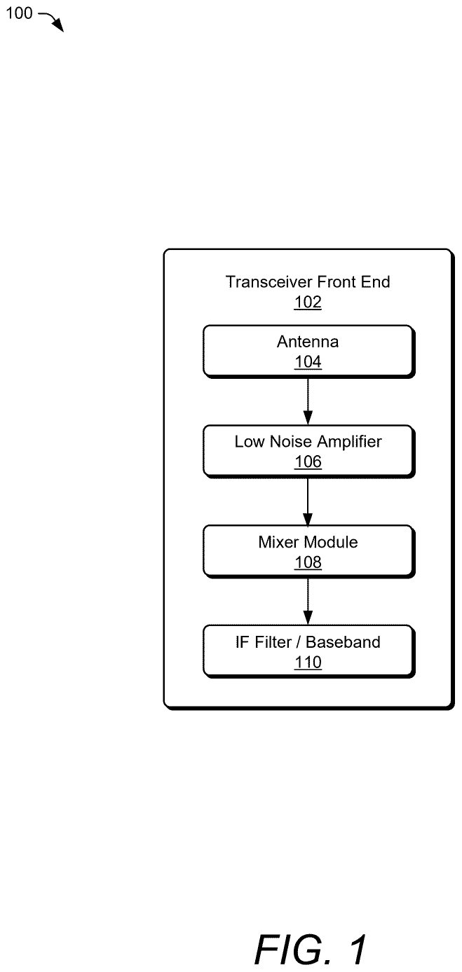

FIG. 1 illustrates a block diagram of an example operating environment 100 for a cross-coupled capacitive network for intermodulation distortion cancellation. The operating environment 100 provides a structural context in which various signal processing operations occur. For example, the operating environment 100 represents a mobile device, a smartphone, a cellular base station, a millimeter-wave communication node, a radar system, an internet-of-things endpoint, or a satellite communication terminal. The operating environment 100 encompasses various hardware and software components that support wireless communications across different frequency bands, such as radio frequency bands, microwave bands, or millimeter-wave bands.

Operating within the operating environment 100, a transceiver front end 102 processes incoming wireless signals from a wireless transmission medium. The transceiver front end 102 acts as a hardware interface that bridges physical electromagnetic waves traveling through the wireless transmission medium with internal digital or analog processing components. The transceiver front end 102 includes a series of hardware stages that sequentially condition, amplify, and translate high-frequency signals into lower-frequency signals that downstream digital processors can decode. In some implementations, the transceiver front end 102 comprises an integrated circuit, such as a radio frequency integrated circuit fabricated on a single semiconductor die. In other implementations, the transceiver front end 102 comprises discrete components mounted on a printed circuit board.

To capture signals from the wireless transmission medium, the transceiver front end 102 includes an antenna 104. The antenna 104 intercepts propagating electromagnetic waves and converts these waves into electrical radio frequency signals. Depending on the specific application of the operating environment 100, the antenna 104 takes various structural forms. For example, the antenna 104 comprises a single dipole antenna, a patch antenna, a horn antenna, or a multi-element phased array antenna that provides directional beamforming capabilities. The antenna 104 routes the generated electrical radio frequency signals further into the transceiver front end 102 for additional processing.

Coupled to the antenna 104, the transceiver front end 102 includes a low noise amplifier 106. The low noise amplifier 106 receives the electrical radio frequency signals from the antenna 104 and amplifies a voltage or power of these electrical radio frequency signals. When amplifying the electrical radio frequency signals, the low noise amplifier 106 adds a relatively small amount of internal noise, which helps maintain a workable signal-to-noise ratio for the overall system. In some cases, the low noise amplifier 106 includes tunable matching networks to support operation across specific millimeter-wave frequency ranges, such as a 28-gigahertz band or a 39-gigahertz band. The low noise amplifier 106 outputs the amplified electrical radio frequency signals to a subsequent stage within the transceiver front end 102.

Following the low noise amplifier 106, the transceiver front end 102 includes a mixer module 108. The mixer module 108 receives the amplified electrical radio frequency signals from the low noise amplifier 106 and performs a frequency translation operation. For example, the mixer module 108 down-converts the high-frequency amplified electrical radio frequency signals into lower intermediate frequency signals by mixing the amplified electrical radio frequency signals with a locally generated reference signal. In some implementations, the mixer module 108 contains a cross-coupled capacitive network to passively cancel intermodulation distortion components, such as third-order intermodulation distortion, that arise during this frequency translation operation. This cancellation helps maintain a linear response profile for the mixer module 108 when processing signals with varying amplitudes.

After the frequency translation operation occurs, the transceiver front end 102 routes the resulting signal to an IF filter/baseband 110. The IF filter/baseband 110 receives the intermediate frequency signals from the mixer module 108 and performs a variety of signal conditioning and data extraction operations. For example, the IF filter/baseband 110 applies a low-pass analog filter or a band-pass analog filter to remove unwanted high-frequency mixing artifacts, adjacent channel interference, or out-of-band noise. Furthermore, the IF filter/baseband 110 can include analog-to-digital converters to digitize the filtered signal, as well as digital signal processors to demodulate the digitized signal and extract an underlying transmitted data payload.

In an example operational sequence, the elements of the operating environment 100 interact to receive and process a high-frequency wireless transmission. Initially, the antenna 104 detects an incoming millimeter-wave signal and converts the incoming millimeter-wave signal into a corresponding radio frequency electrical current. The antenna 104 passes this unamplified signal to the low noise amplifier 106. The low noise amplifier 106 then scales up the amplitude of the unamplified signal to a level suitable for subsequent frequency translation, generating an amplified signal with a constrained noise contribution.

Continuing the operational sequence, the low noise amplifier 106 provides the amplified signal to the mixer module 108. The mixer module 108 mixes the amplified signal with a local oscillator signal to shift the data to a lower intermediate frequency. During this mixing operation, internal components of the mixer module 108 cross-couple portions of the local oscillator signal to cancel internally generated intermodulation distortion, thereby maintaining a linear intermediate frequency signal. Finally, the mixer module 108 outputs this linear intermediate frequency signal to the IF filter/baseband 110. The IF filter/baseband 110 filters out out-of-band artifacts and converts analog waveforms into digital bits, which the operating environment 100 then uses for computing, display, or further network routing tasks.

### Example Devices and Systems

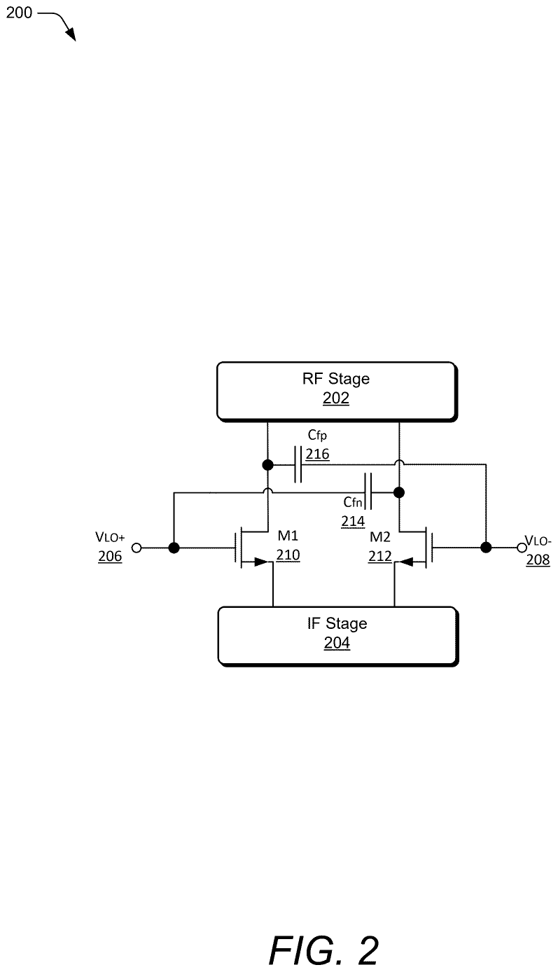

FIG. 2 illustrates a mixer circuit block diagram 200 of an example mixer circuit for a cross-coupled capacitive network for intermodulation distortion cancellation. The mixer circuit block diagram 200 represents a hardware architecture that facilitates frequency translation operations while managing the linearity of resulting signals. In some implementations, the mixer circuit block diagram 200 represents a component embedded within a monolithic semiconductor substrate, such as a complementary metal-oxide-semiconductor radio frequency integrated circuit, or a discrete multi-chip module. The components depicted in the mixer circuit block diagram 200 interact to receive high-frequency electromagnetic signals, mix the high-frequency electromagnetic signals with locally generated reference signals, and output corresponding lower-frequency signals for downstream baseband processing.

The mixer circuit block diagram 200 includes a radio frequency (RF) stage 202. The radio frequency (RF) stage 202 receives an incoming radio frequency signal, such as an amplified signal originating from an upstream amplifier. Depending on the specific design, the radio frequency (RF) stage 202 takes various forms. For example, the radio frequency (RF) stage 202 can comprise a passive network, such as a balun or a series of matching inductors, that routes an incoming voltage. Alternatively, the radio frequency (RF) stage 202 can comprise an active transconductance network that converts an incoming radio frequency voltage into a corresponding radio frequency current before passing the signal to subsequent mixing components.

Coupled to the lower portion of the mixer circuit block diagram 200, an intermediate frequency (IF) stage 204 receives an output signal generated after the frequency translation process. The intermediate frequency (IF) stage 204 extracts the down-converted signal and prepares the down-converted signal for further downstream processing. In some implementations, the intermediate frequency (IF) stage 204 comprises an active transimpedance amplifier that receives a translated current signal from core mixing components and converts that current into a measurable output voltage. In other configurations, the intermediate frequency (IF) stage 204 serves as a passive output node or filter network that directly routes an extracted intermediate frequency voltage to a separate baseband processor.

To facilitate the frequency translation, the mixer circuit block diagram 200 utilizes a differential local oscillator signal provided via a first local oscillator node (VLO+) 206 and a second local oscillator node (VLO−) 208. The first local oscillator node (VLO+) 206 and the second local oscillator node (VLO−) 208 receive distinct, offset phases of a continuous reference waveform generated by an oscillator. For example, the first local oscillator node (VLO+) 206 receives a positive phase (e.g., a first LO phase) of a differential signal, while the second local oscillator node (VLO−) 208 receives a negative, anti-phase portion (e.g., a second LO phase) of that same differential signal. These complementary signals provide oscillating timing references that drive active switching elements of the mixer circuit block diagram 200.

The active switching core of the mixer circuit block diagram 200 comprises a first transistor (M1) 210 and a second transistor (M2) 212. The first transistor (M1) 210 and the second transistor (M2) 212 periodically alter a conductive path of the signals received from the radio frequency (RF) stage 202. As illustrated, a control terminal of the first transistor (M1) 210 couples directly to the first local oscillator node (VLO+) 206, and a control terminal of the second transistor (M2) 212 couples directly to the second local oscillator node (VLO−) 208. Upper output terminals (e.g., a first output terminal and a second output terminal) of the first transistor (M1) 210 and the second transistor (M2) 212 couple to the radio frequency (RF) stage 202, while lower reference terminals (e.g., a first reference terminal and a second reference terminal) couple to the intermediate frequency (IF) stage 204. By driving the respective control terminals with the complementary local oscillator signals, the first local oscillator node (VLO+) 206 and the second local oscillator node (VLO−) 208 cause the first transistor (M1) 210 and the second transistor (M2) 212 to alternate their conductive states to execute the mixing operation. In some implementations, the first transistor (M1) 210 and the second transistor (M2) 212 are configured to be biased in a triode region to operate as variable resistors during the mixing operation.

To manage signal linearity during this mixing operation, the mixer circuit block diagram 200 incorporates a first capacitor (e.g., the first cross-coupled capacitor (Cfn) 214) and a second capacitor (e.g., the second cross-coupled capacitor (Cfp) 216). The first cross-coupled capacitor (Cfn) 214 and the second cross-coupled capacitor (Cfp) 216 form a passive network that introduces a specific, controlled signal pathway across the mixing core. As shown in the diagram, the first cross-coupled capacitor (Cfn) 214 couples the first local oscillator node (VLO+) 206 to the upper output terminal of the second transistor (M2) 212. Conversely, the second cross-coupled capacitor (Cfp) 216 couples the second local oscillator node (VLO−) 208 to the upper output terminal of the first transistor (M1) 210. This structural arrangement physically routes a portion of the local oscillator signal driving one transistor to the output terminal of the opposing transistor. In some implementations, the first cross-coupled capacitor (Cfn) 214 and the second cross-coupled capacitor (Cfp) 216 comprise static structures (e.g., metal-on-metal) fabricated on a semiconductor die. In some implementations, a first capacitance value of the first cross-coupled capacitor (Cfn) 214 is configured to substantially match a parasitic capacitance between the second control terminal and the second output terminal of the second transistor (M2) 212. Similarly, a second capacitance value of the second cross-coupled capacitor (Cfp) 216 is configured to substantially match a parasitic capacitance between the first control terminal and the first output terminal of the first transistor (M1) 210.

In an example operational sequence, the components of the mixer circuit block diagram 200 interact to translate a frequency while passively managing intermodulation distortion. The radio frequency (RF) stage 202 receives an incoming high-frequency signal and applies the high-frequency signal to the upper output terminals of the first transistor (M1) 210 and the second transistor (M2) 212. Simultaneously, an external oscillator drives the first local oscillator node (VLO+) 206 with a positive signal phase and the second local oscillator node (VLO−) 208 with a negative signal phase. This differential driving causes the first transistor (M1) 210 and the second transistor (M2) 212 to rapidly switch, mixing the incoming high-frequency signal down to an intermediate frequency signal that flows toward the intermediate frequency (IF) stage 204.

While this rapid switching occurs, the first cross-coupled capacitor (Cfn) 214 and the second cross-coupled capacitor (Cfp) 216 actively route portions of the differential local oscillator signals to counteract internal distortion. For example, as the first transistor (M1) 210 generates third-order intermodulation distortion at its output terminal, the second cross-coupled capacitor (Cfp) 216 applies an anti-phase portion of the signal from the second local oscillator node (VLO−) 208 directly to that same output terminal. Because this applied signal is 180 degrees out of phase with the generated distortion, the two signals destructively interfere and cancel each other out. Similarly, the first cross-coupled capacitor (Cfn) 214 applies an anti-phase portion of the signal from the first local oscillator node (VLO+) 206 to the output terminal of the second transistor (M2) 212, canceling distortion at that node. The intermediate frequency (IF) stage 204 then extracts a linear down-converted signal having reduced intermodulation artifacts for use by the communication system.

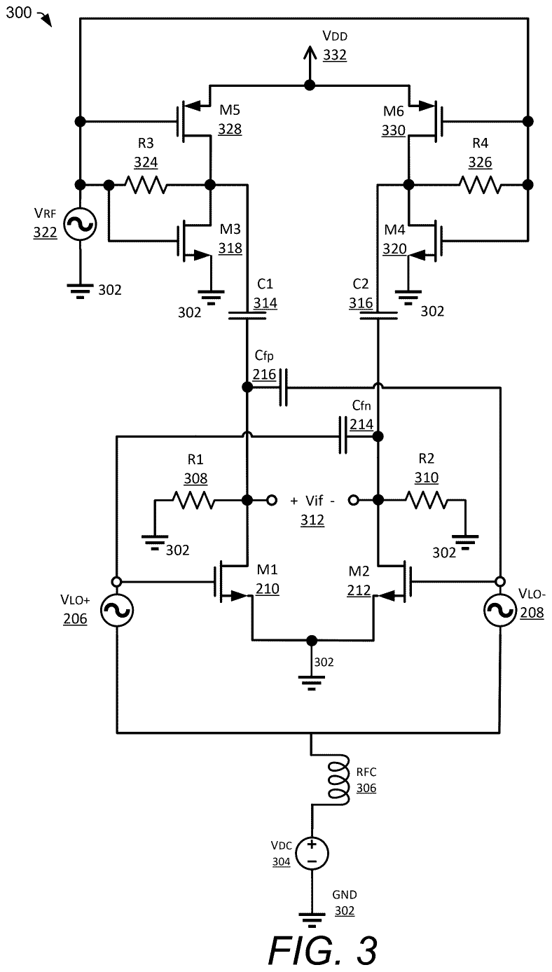

FIG. 3 illustrates a mixer circuit schematic 300 of an example mixer circuit for a cross-coupled capacitive network for intermodulation distortion cancellation. The mixer circuit schematic 300 depicts a detailed component-level arrangement of transistors, capacitors, resistors, and signal sources that interact to translate a high-frequency input signal into a lower-frequency output signal. In some implementations, the mixer circuit schematic 300 represents a hardware topology fabricated on a single semiconductor substrate, such as a complementary metal-oxide-semiconductor integrated circuit. In other examples, the mixer circuit schematic 300 comprises discrete electronic components mounted on a printed circuit board.

The mixer circuit schematic 300 incorporates a first local oscillator node (VLO+) 206 and a second local oscillator node (VLO−) 208. The first local oscillator node (VLO+) 206 and the second local oscillator node (VLO−) 208 provide a differential local oscillator signal to a mixing core to drive the frequency translation operations. The mixing core includes a first transistor (M1) 210 and a second transistor (M2) 212. The first local oscillator node (VLO+) 206 couples to a gate of the first transistor (M1) 210, and the second local oscillator node (VLO−) 208 couples to a gate of the second transistor (M2) 212. To route anti-phase portions of the differential local oscillator signal, the mixer circuit schematic 300 utilizes a first cross-coupled capacitor (Cfn) 214 and a second cross-coupled capacitor (Cfp) 216. The first cross-coupled capacitor (Cfn) 214 couples the first local oscillator node (VLO+) 206 to a drain of the second transistor (M2) 212. The second cross-coupled capacitor (Cfp) 216 couples the second local oscillator node (VLO−) 208 to a drain of the first transistor (M1) 210.

To establish voltage reference levels and provide steady-state biasing, the mixer circuit schematic 300 connects various components to a ground node 302. For example, a source of the first transistor (M1) 210 and a source of the second transistor (M2) 212 couple directly to the ground node 302. A direct current voltage source (VDC) 304 supplies a direct current bias voltage to the local oscillator nodes. A radio frequency choke inductor (RFC) 306 couples the direct current voltage source (VDC) 304 to a lower terminal of the first local oscillator node (VLO+) 206 and a lower terminal of the second local oscillator node (VLO−) 208. The radio frequency choke inductor (RFC) 306 allows the direct current bias voltage to pass while impeding high-frequency alternating current signals from feeding back into the direct current voltage source (VDC) 304. A first bias resistor (R1) 308 couples the drain (output terminal) of the first transistor (M1) 210 to the ground node 302, and a second bias resistor (R2) 310 couples the drain (output terminal) of the second transistor (M2) 212 to the ground node 302. An intermediate frequency output voltage (Vif) 312 spans the drain of the first transistor (M1) 210 and the drain of the second transistor (M2) 212, representing the down-converted differential signal.

The mixer circuit schematic 300 further features a transconductance stage coupled to the mixing core via a direct current (DC) blocking network comprising a first DC blocking capacitor C1 314 and a second DC blocking capacitor C2 316. The first DC blocking capacitor C1 314 couples the transconductance stage to the drain of the first transistor (M1) 210, and the second DC blocking capacitor C2 316 couples the transconductance stage to the drain of the second transistor (M2) 212. The first DC blocking capacitor C1 314 and the second DC blocking capacitor C2 316 isolate direct current voltages of the transconductance stage from the mixing core. The transconductance stage includes a transistor M3 318 and a transistor M4 320, which have source terminals coupled to the ground node 302. An input radio frequency voltage (VRF) 322 supplies a radio frequency signal to a gate of the transistor M3 318. A resistor R3 324 couples the gate of the transistor M3 318 to a drain of the transistor M3 318 to provide localized feedback. Similarly, a resistor R4 326 couples a gate of the transistor M4 320 to a drain of the transistor M4 320. A transistor M5 328 couples with the transistor M3 318, sharing a common gate connection and a common drain connection. A transistor M6 330 couples with the transistor M4 320, sharing a common gate connection and a common drain connection. A supply voltage VDD 332 couples to a source of the transistor M5 328 and a source of the transistor M6 330 to provide electrical power to the transconductance stage.

In an example operational sequence, the components of the mixer circuit schematic 300 interact to convert a high-frequency input signal into a lower-frequency output signal while suppressing internal distortion. Initially, the input radio frequency voltage (VRF) 322 applies a high-frequency radio frequency signal to the transconductance stage. Actuated by the input radio frequency voltage (VRF) 322, the transistor M3 318, the transistor M4 320, the transistor M5 328, and the transistor M6 330 draw electrical power from the supply voltage VDD 332 to convert the high-frequency radio frequency signal into a proportional radio frequency current. The first DC blocking capacitor C1 314 and the second DC blocking capacitor C2 316 pass this radio frequency current downward into the drain of the first transistor (M1) 210 and the drain of the second transistor (M2) 212. During this process, the first bias resistor (R1) 308 and the second bias resistor (R2) 310 establish steady direct current operating voltages at the drains of the mixing core relative to the ground node 302.

Concurrently with the current injection, the first local oscillator node (VLO+) 206 and the second local oscillator node (VLO−) 208 drive the gate of the first transistor (M1) 210 and the gate of the second transistor (M2) 212 with the differential local oscillator signal. The direct current voltage source (VDC) 304, coupled through the radio frequency choke inductor (RFC) 306, applies a steady bias to this differential local oscillator signal. In response to the differential local oscillator signal, the first transistor (M1) 210 and the second transistor (M2) 212 alternate conductive states to commutate the radio frequency current, generating the intermediate frequency output voltage (Vif) 312. As the mixing core commutates the current, the first cross-coupled capacitor (Cfn) 214 couples an anti-phase portion of the differential local oscillator signal from the first local oscillator node (VLO+) 206 to the drain of the second transistor (M2) 212. Similarly, the second cross-coupled capacitor (Cfp) 216 couples an anti-phase portion of the differential local oscillator signal from the second local oscillator node (VLO−) 208 to the drain of the first transistor (M1) 210. These cross-coupled signals destructively interfere with intermodulation distortion components generated by the mixing core, yielding a linear intermediate frequency output voltage (Vif) 312 for downstream processing.

### Example Data

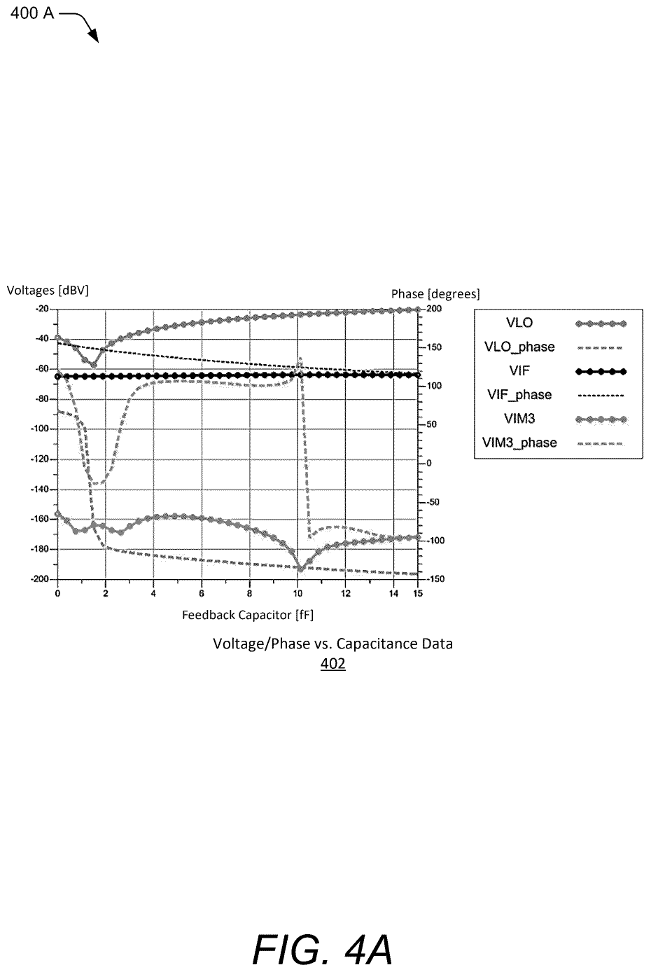

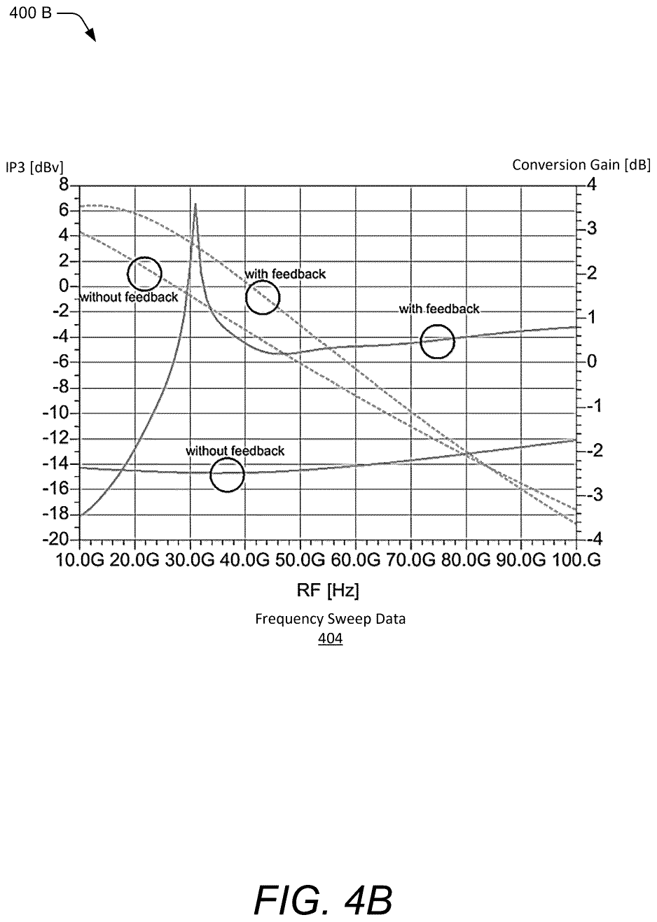

FIG. 4A illustrates a voltage/phase vs. capacitance graph for a cross-coupled capacitive network for intermodulation distortion cancellation. A voltage/phase vs. capacitance graph 400A provides a visual representation of how varying a feedback capacitance value influences various electrical responses of a mixer circuit. In some implementations, a testing apparatus or a circuit simulation environment generates the voltage/phase vs. capacitance graph 400A to evaluate signal behaviors, phase shifts, and voltage amplitudes under different physical component configurations.

The voltage/phase vs. capacitance graph 400A defines a multi-dimensional coordinate system to plot these electrical responses. A horizontal axis of the voltage/phase vs. capacitance graph 400A represents a feedback capacitance value, measured in femtofarads, ranging from zero to fifteen femtofarads. A primary vertical axis on a left side of the voltage/phase vs. capacitance graph 400A indicates signal magnitude or voltages in decibel-volts, scaling from negative two hundred to negative twenty. A secondary vertical axis on a right side of the voltage/phase vs. capacitance graph 400A indicates a signal phase in degrees, ranging from negative one hundred fifty to positive two hundred. This dual-axis arrangement allows a computing device to simultaneously plot amplitude changes and phase shifts of multiple signals across a swept capacitance range.

Plotted within this coordinate system, the voltage/phase vs. capacitance graph 400A presents a voltage/phase vs. capacitance data 402. The voltage/phase vs. capacitance data 402 includes multiple discrete data series corresponding to different signal components at an output node of a mixer circuit. For example, a legend indicates that the voltage/phase vs. capacitance data 402 includes amplitude and phase curves for a local oscillator signal, an intermediate frequency signal, and a third-order intermodulation distortion component. Each data point within the voltage/phase vs. capacitance data 402 reflects an electrical state of a respective signal at a specific cross-coupled capacitance value.

Within the voltage/phase vs. capacitance data 402, an intermediate frequency signal amplitude curve remains substantially flat across the horizontal axis. Specifically, as a simulated testing device increases the capacitance value from zero to fifteen femtofarads, the intermediate frequency signal amplitude maintains a steady level near negative sixty-five decibel-volts. This portion of the voltage/phase vs. capacitance data 402 demonstrates that altering the cross-coupled capacitance does not significantly alter a conversion gain of a target fundamental output signal. An associated intermediate frequency phase curve of the voltage/phase vs. capacitance data 402 also exhibits a stable trajectory without sudden discontinuities, indicating consistent timing characteristics for the target signal regardless of the applied capacitance.

Conversely, the voltage/phase vs. capacitance data 402 exhibits behavior for the intermodulation distortion components. A third-order intermodulation distortion amplitude curve starts near negative one hundred fifty-five decibel-volts at zero femtofarads, fluctuates slightly, and then drops to a signal null near negative one hundred ninety decibel-volts when the capacitance reaches approximately ten femtofarads. Coinciding with this amplitude null, a third-order intermodulation distortion phase curve of the voltage/phase vs. capacitance data 402 undergoes a phase inversion. This discontinuity in the voltage/phase vs. capacitance data 402 indicates a point of destructive interference, where an injected anti-phase signal cancels a generated distortion component. Additionally, the voltage/phase vs. capacitance data 402 includes a local oscillator voltage curve that exhibits a dip at a lower capacitance value before gradually rising.

In an example operational scenario, a circuit designer analyzes the voltage/phase vs. capacitance data 402 to configure a tunable mixer circuit. The circuit designer then scans the voltage/phase vs. capacitance data 402 to identify a targeted capacitance value that triggers the signal null in the intermodulation distortion amplitude. Upon locating this point at approximately ten femtofarads using the voltage/phase vs. capacitance data 402, the circuit designer sets a programmable capacitor bank to this targeted value. By leveraging the relationships illustrated in the voltage/phase vs. capacitance data 402, a system applies a passive cancellation technique that reduces intermodulation distortion while maintaining the integrity of the intermediate frequency signal.

FIG. 4B illustrates an IIP3 vs. frequency sweep graph 400B depicting frequency sweep data for a cross-coupled capacitive network for intermodulation distortion cancellation. The IIP3 vs. frequency sweep graph 400B provides a visual representation of how a mixer circuit performs across a wide spectrum of radio frequencies. In some implementations, a circuit simulation environment, a laboratory spectrum analyzer, or an automated testing apparatus generates the IIP3 vs. frequency sweep graph 400B to evaluate the electrical characteristics of a hardware design under varying high-frequency conditions.

To present these electrical characteristics, the automated testing apparatus defines a two-dimensional coordinate system with dual vertical axes for the IIP3 vs. frequency sweep graph 400B. The automated testing apparatus scales a horizontal axis of the IIP3 vs. frequency sweep graph 400B to represent an input radio frequency measured in hertz, sweeping from a lower bound of ten gigahertz up to an upper bound of one hundred gigahertz. The automated testing apparatus scales a primary vertical axis positioned on a left side of the IIP3 vs. frequency sweep graph 400B to quantify a third-order input intercept point magnitude, labeled as IIP3, measured in decibel-volts from negative twenty to positive eight. Furthermore, the automated testing apparatus scales a secondary vertical axis positioned on a right side of the IIP3 vs. frequency sweep graph 400B to quantify a conversion gain measured in decibels, scaling from negative four to positive four. This dual-axis structure allows the automated testing apparatus to concurrently evaluate both a linearity metric and a signal translation strength of a circuit as the input frequency sweeps across the defined spectrum.

The automated testing apparatus plots a frequency sweep data 404 within this coordinate framework of the IIP3 vs. frequency sweep graph 400B. The frequency sweep data 404 encompasses multiple discrete data series or continuous curves that compare the performance of a mixer circuit operating with a capacitive feedback network against a mixer circuit operating without such a network. Specifically, the automated testing apparatus plots solid lines within the frequency sweep data 404 to represent the third-order input intercept point responses and dashed lines to represent the conversion gain responses. By grouping these specific curves together, the frequency sweep data 404 illustrates the isolated electrical effects introduced by applying a cross-coupled capacitive signal pathway within a mixing core.

Examining the dashed lines within the frequency sweep data 404, the automated testing apparatus records the conversion gain behavior across the frequency spectrum. The frequency sweep data 404 illustrates that the conversion gain gradually decreases as the input radio frequency increases toward one hundred gigahertz, which reflects high-frequency signal attenuation. Notably, the frequency sweep data 404 shows that the conversion gain curve for a “with feedback” configuration closely evaluates the conversion gain curve for a “without feedback” configuration. This parallel relationship depicted in the frequency sweep data 404 indicates that introducing the capacitive feedback network does not fundamentally alter a primary signal amplification and translation capability of an underlying mixer circuit.

Examining the solid lines within the frequency sweep data 404, the automated testing apparatus records the third-order input intercept point behavior, which serves as a metric for signal linearity and distortion resilience. The frequency sweep data 404 illustrates that the “without feedback” curve remains relatively flat and low, hovering around negative fourteen decibel-volts across the frequency spectrum. In contrast, the frequency sweep data 404 shows the “with feedback” curve exhibiting a distinct, upward peak, near thirty-one gigahertz, where the intercept point rapidly rises to approximately positive six decibel-volts. This upward peak in the frequency sweep data 404 indicates a specific operational frequency where the capacitive feedback network actively and destructively cancels intermodulation distortion, thereby yielding a linear signal output at that targeted frequency.

In an example operational sequence, a circuit designer evaluates the frequency sweep data 404 to configure a programmable transceiver system. The circuit designer parses the numerical values of the frequency sweep data 404 to identify the frequency location of the third-order input intercept point peak. Upon detecting this peak near thirty-one gigahertz within the frequency sweep data 404, the circuit designer tunes a local oscillator or adjusts a switchable capacitor bank to align a primary operating channel with this linear frequency zone. Through this process, a communication device utilizes the relationships mapped in the frequency sweep data 404 to select frequency bands that offer high resilience to intermodulation distortion during wireless transmissions.

### Example Methods

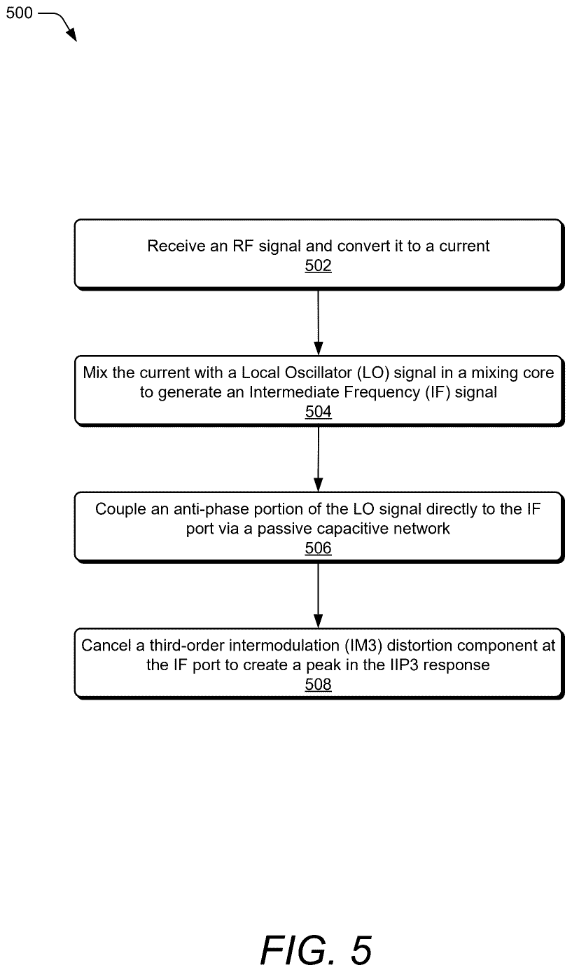

FIG. 5 illustrates an example method 500 for a cross-coupled capacitive network for intermodulation distortion cancellation in accordance with one or more aspects. Operations of the method 500 are implemented by or with transceiver front end 102.

Example method 500 is described with reference to FIG. 5 in accordance with one or more aspects of a cross-coupled capacitive network for intermodulation distortion cancellation. Generally, the method 500 illustrates sets of operations (or acts) performed in, but not necessarily limited to, the order or combinations in which the operations are shown herein. Further, any of one or more of the operations may be repeated, combined, reorganized, omitted, or linked to provide a variety of additional and/or alternate methods. In portions of the following discussion, reference may be made to the entities of FIGS. 1-4B, reference to which is made for example only. The systems and methods described in this disclosure are not limited to embodiment or performance by one entity or multiple entities operating in relation to a cross-coupled capacitive network for intermodulation distortion cancellation.

FIG. 5 illustrates a flow diagram of an example method flowchart 500 for a cross-coupled capacitive network for intermodulation distortion cancellation. A mixer circuit or a similar communication device performs the operations of the method flowchart 500 to process high-frequency wireless signals while managing signal linearity. In some implementations, the operations described in the method flowchart 500 occur continuously and concurrently as a hardware architecture receives incoming electromagnetic waves from a wireless transmission medium and translates those waves into baseband data.

At 502, a mixer circuit receives an RF signal and converts it to a current. To execute this operation, the mixer circuit captures an incoming voltage waveform and applies this voltage waveform to an internal transconductance stage. The transconductance stage acts as a voltage-to-current converter, drawing electrical power from a supply line to generate a proportional time-varying current that represents the received data. For example, a millimeter-wave communication device receives a 28-gigahertz radio frequency voltage signal from a cellular antenna and drives a set of input field-effect transistors to translate that voltage signal into a corresponding radio frequency current, preparing the incoming information for a subsequent frequency translation.

At 504, the mixer circuit mixes the current with a local oscillator (LO) signal in a mixing core to generate an intermediate frequency (IF) signal. During this stage, the mixer circuit directs the generated radio frequency current into a set of active switching transistors while simultaneously driving control terminals of those active switching transistors with a differential local oscillator waveform. This simultaneous interaction causes the active switching transistors to commutate the radio frequency current at a frequency of the local oscillator waveform, shifting the high-frequency information down to a lower frequency band. For example, the millimeter-wave communication device applies a differential local oscillator signal to commutate the radio frequency current passing through the mixing core, thereby outputting a lower-frequency intermediate frequency signal at a set of output terminals for downstream baseband processing.

At 506, the mixer circuit couples an anti-phase portion of the LO signal directly to the IF port via a passive capacitive network. As the mixing core commutates the current, internal routing traces and cross-coupled capacitors physically tap into local oscillator input lines and route an inverted phase of the local oscillator waveform across the mixing core to an opposing output terminal. By utilizing passive capacitors, this routing bypasses the active switching path and injects an oscillator timing signal directly into an intermediate frequency output junction. For example, the mixer circuit routes a negative phase of a local oscillator signal through a fixed femtofarad capacitor directly into a positive intermediate frequency output node, introducing an inverted waveform into the translated signal path.

At 508, the mixer circuit cancels a third-order intermodulation (IM3) distortion component at the IF port to create an upward peak in the IIP3 response. The mixer circuit achieves this cancellation because the anti-phase portion of the local oscillator signal, previously routed through the passive capacitive network, destructively interferes with harmonic distortion artifacts internally generated by the active switching transistors during the mixing process. As the injected anti-phase signal merges with the distortion artifact at the output node, the two waveforms negate each other, which structurally modifies the linearity of the system at that specific operating point. For example, an automated tuning system sweeps input frequencies across a spectrum and identifies that the destructive interference of the cross-coupled local oscillator signal suppresses a corresponding third-order intermodulation spike, producing an upward peak, in a third-order input intercept point linearity curve at a targeted operating frequency.

### Conclusion

Although aspects of a cross-coupled capacitive network for intermodulation distortion cancellation have been described in language specific to features and/or methods, the subject of the appended claims is, as recited by any of the previous examples, not necessarily limited to the specific features or methods described. Rather, the specific features and methods are disclosed as example implementations of a cross-coupled capacitive network for intermodulation distortion cancellation, and other equivalent features and methods are intended to be within the scope of the appended claims. Further, various aspects of a cross-coupled capacitive network for intermodulation distortion cancellation are described, and it is to be appreciated that each described aspect may be implemented independently or in connection with one or more other described aspects.

What is claimed is:

1. A mixer circuit, comprising:
a first local oscillator (LO) node and a second LO node configured to receive a differential LO signal comprising a first LO phase and a second LO phase;
a mixing core comprising a first transistor and a second transistor, the first transistor comprising a first output terminal and a first control terminal, the first control terminal coupled to the first LO node to receive the first LO phase, and the second transistor comprising a second output terminal and a second control terminal, the second control terminal coupled to the second LO node to receive the second LO phase;
a radio frequency (RF) stage coupled to the first output terminal and the second output terminal;
an intermediate frequency (IF) stage coupled to the mixing core and configured to output an IF signal; and
a cross-coupled capacitive network comprising a first capacitor coupled between the first LO node and the second output terminal, and a second capacitor coupled between the second LO node and the first output terminal.

2. The mixer circuit of claim 1, wherein the cross-coupled capacitive network is configured to couple an anti-phase portion of the differential LO signal to the second output terminal and the first output terminal to cancel an intermodulation distortion component generated by the mixing core.

3. The mixer circuit of claim 2, wherein the intermodulation distortion component comprises a third-order intermodulation (IM3) distortion component, and wherein the first capacitor and the second capacitor comprise capacitance values sized to produce a peak in a third-order input intercept point (IIP3) response curve of the mixer circuit based on canceling the IM3 distortion component.

4. The mixer circuit of claim 1, wherein the first transistor and the second transistor are configured to be biased in a triode region to operate as variable resistors.

5. The mixer circuit of claim 1, wherein the RF stage comprises a transconductance stage configured to convert an input RF voltage into an RF current, and wherein the transconductance stage is configured to apply the RF current to the first output terminal and the second output terminal.

6. The mixer circuit of claim 5, further comprising a direct current (DC) blocking network comprising a first DC blocking capacitor coupled between the transconductance stage and the first output terminal, and a second DC blocking capacitor coupled between the transconductance stage and the second output terminal.

7. The mixer circuit of claim 1, wherein the IF stage is coupled to the first output terminal and the second output terminal, and wherein the IF stage is configured to extract the IF signal as an IF voltage.

8. The mixer circuit of claim 1, wherein the first transistor further comprises a first reference terminal, wherein the second transistor further comprises a second reference terminal, wherein the IF stage is coupled to the first reference terminal and the second reference terminal, and wherein the IF stage comprises a transimpedance amplifier configured to receive an IF current and convert the IF current into an IF voltage.

9. The mixer circuit of claim 1, further comprising a first bias resistor coupled to the first output terminal and a second bias resistor coupled to the second output terminal, the first bias resistor and the second bias resistor configured to provide a direct current (DC) bias voltage to the mixing core.

10. The mixer circuit of claim 1, wherein a first capacitance value of the first capacitor is configured to substantially match a first parasitic capacitance between the second control terminal and the second output terminal, and wherein a second capacitance value of the second capacitor is configured to substantially match a second parasitic capacitance between the first control terminal and the first output terminal.
